(19) United States
(12) Patent Application Publication
(10) Pub. No.: US 2025/0279147 A1
(43) Pub. Date: Sep. 4, 2025

(54) BLOCK REOPENING PROTOCOL IN A MEMORY SUB-SYSTEM

(71) Applicant: Micron Technology, Inc., Boise, ID (US)

(72) Inventors: Zhongguang Xu, San Jose, CA (US); Wei Wang, Fremont, CA (US)

(21) Appl. No.: 19/045,466

(22) Filed: Feb. 4, 2025

Related U.S. Application Data
(60) Provisional application No. 63/559,399, filed on Feb. 29, 2024.

(51) Int. Cl. G11C 16/34; G11C 16/08; G11C 16/10

(52) U.S. Cl. CPC G11C 16/349; G11C 16/08; G11C 16/102

(57) ABSTRACT

A system comprises a memory device and a processing device, operatively coupled with the memory device, to perform operations including identifying a block of the memory device, wherein the block is closed, and wherein the block comprises a plurality of wordlines; performing a data integrity scan on the block to determine one or more reliability statistics associated with the block; in response to determining that at least one of the one or more reliability statistics satisfies a first threshold criterion, associating the block with a first plurality of blocks, wherein each block of the first plurality of blocks is associated with at least one or more reliability statistics that satisfies the first threshold criterion; and sending a programming command to program one or more wordlines of the block, wherein the one or more wordlines are adjacent to a last programmed wordline of the block before the block was closed.

### RELATED APPLICATIONS

This application claims the benefit of U.S. Provisional Patent Application No. 63/559,399, filed Feb. 29, 2024, the entire contents of which are hereby incorporated by reference here.

### TECHNICAL FIELD

Embodiments of the disclosure relate generally to memory sub-systems, and more specifically, relate to a block reopening protocol in a memory sub-system.

### BACKGROUND

A memory sub-system can include one or more memory devices that store data. The memory devices can be, for example, non-volatile memory devices and volatile memory devices. In general, a host system can utilize a memory sub-system to store data at the memory devices and to retrieve data from the memory devices.

### BRIEF DESCRIPTION OF THE DRAWINGS

The present disclosure will be understood more fully from the detailed description given below and from the accompanying drawings of various embodiments of the disclosure.

FIG. 1A illustrates an example computing system that includes a memory sub-system, in accordance with some embodiments of the present disclosure.

FIG. 1B is a block diagram of a memory device in communication with a memory sub-system controller of a memory sub-system, in accordance with some embodiments of the present disclosure.

FIG. 2 is a schematic diagram of portions of an array of memory cells as could be used in a memory of the type described with reference to FIG. 1B, in accordance with some embodiments of the present disclosure.

FIG. 3A is a diagram illustrating an example set of blocks of a memory device, in accordance with some embodiments of the present disclosure.

FIG. 3B is a diagram illustrating another example set of blocks of a memory device, in accordance with some embodiments of the present disclosure.

FIG. 3C is a diagram illustrating another example set of blocks of a memory device, in accordance with some embodiments of the present disclosure.

FIG. 4 is a flow diagram of an example method of a block reopening protocol in a memory sub-system, in accordance with some embodiments of the present disclosure.

FIG. 5 is a block diagram of an example computer system in which embodiments of the present disclosure may operate.

### DETAILED DESCRIPTION

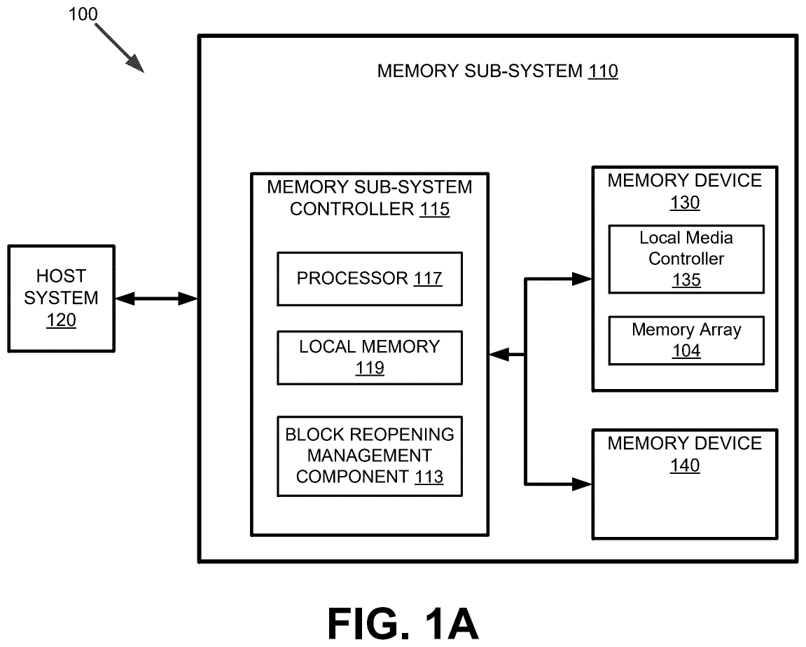

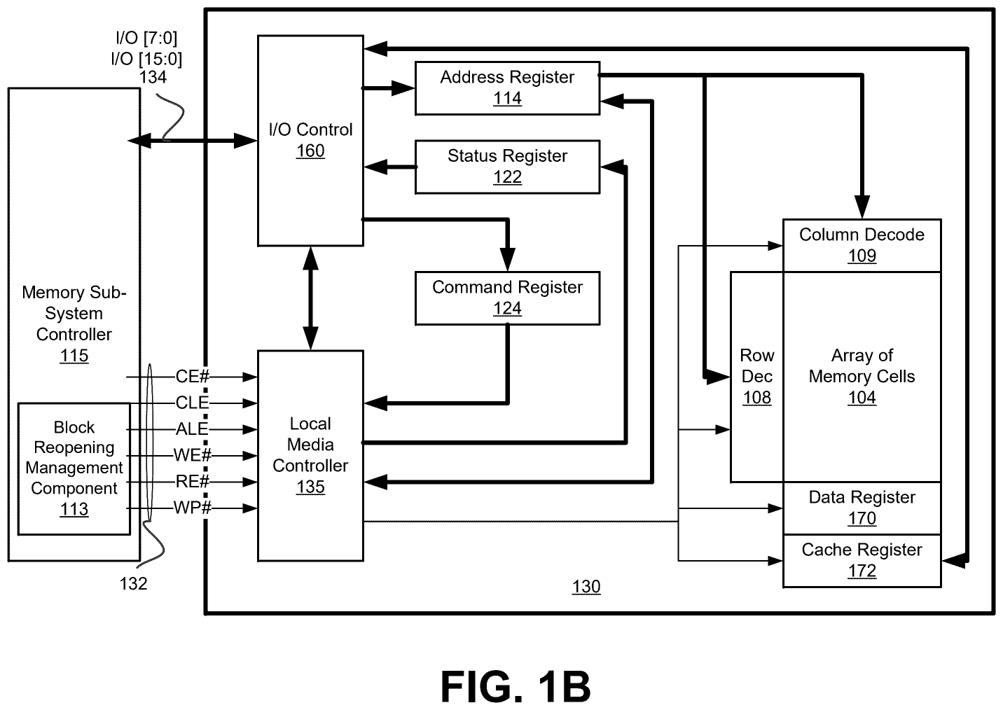

Aspects of the present disclosure are directed to a block reopening protocol in a memory sub-system. A memory sub-system can be a storage device, a memory module, or a hybrid of a storage device and memory module. Examples of storage devices and memory modules are described below in conjunction with FIG. 1A. In general, a host system can utilize a memory sub-system that includes one or more components, such as memory devices that store data. The host system can provide data to be stored at the memory sub-system and can request data to be retrieved from the memory sub-system.

A memory sub-system can include high-density non-volatile memory devices where retention of data is desired when no power is supplied to the memory device. For example, NAND memory, such as 3D flash NAND memory, offers storage in the form of compact, high-density configurations. A non-volatile memory device is a package of one or more dice, each including one or more planes. For some types of non-volatile memory devices (e.g., NAND memory), each plane includes a set of physical blocks. Each block includes a set of pages. Each page includes a set of memory cells (“cells”). A cell is an electronic circuit that stores information. Depending on the cell type, a cell can store one or more bits of binary information and has various logic states that correlate to the number of bits being stored. The logic states can be represented by binary values, such as “0” and “1”, or combinations of such values.

A memory device can be made up of bits arranged in a two-dimensional or a three-dimensional grid. Memory cells are formed onto a silicon wafer in an array of columns (also hereinafter referred to as bitlines) and rows (also hereinafter referred to as wordlines). A wordline can refer to one or more rows of memory cells of a memory device that are used with one or more bitlines to generate the address of each of the memory cells. The intersection of a bitline and wordline constitutes the address of the memory cell. A block hereinafter refers to a unit of the memory device used to store data and can include a group of memory cells, a wordline group, a wordline, or individual memory cells. One or more blocks can be grouped together to form separate partitions (e.g., planes) of the memory device in order to allow concurrent operations to take place on each plane.

One phenomenon observed in memory devices is threshold voltage (VT) distribution shift, also referred to herein as temporal voltage shift (TVS). There are a number of different causes of TVS, including cell-to-cell (C2C) coupling which impacts the observable level of charge in neighboring memory cells, the back pattern effect which includes an overall Vr shift due to increased array loading resistance especially prominent in earlier programmed cells, and slow charge loss (SCL) which causes vertical charge loss and lateral charge migration. For example, with respect to programmed pages of a block, SCL can cause VT distributions of the programmed pages to shift towards lower voltages as charge diminishes over time and/or with respect to changes in temperature. That is, SCL and the corresponding VT distribution shift towards lower voltages can be proportional to the amount of time elapsed since data was programmed. Conversely, with respect to erased pages (e.g., erased pages of partially programmed blocks), storage charge gain (SCG) can cause VT distributions of the erased pages to shift towards higher voltages.

In certain memory sub-systems, to address TVS, a memory sub-system controller can implement a block usage policy that closes a block after a certain period of time (e.g., four hours) has passed since the block was first written. For example, the memory sub-system controller can maintain a timer or counter that is started when the first page of a block is written and expires after the period of time is reached. At that time, the block is logically closed, such that the additional pages of the block cannot be written, even if the block remains physically open (e.g., has additional capacity in unwritten pages). The block usage policy prevents large variations in rates of charge loss among the programmed memory cells associated with different wordlines (e.g., cells associated with earlier programmed wordlines can exhibit greater charge loss than cells associated with more recently programmed wordlines) by limiting the time between when different cells of the same block are programmed. Such a block remains partially written (also referred to as a “partial” or “open” block herein) because it has not been completely written. For example, a block can be partially written when, after writing to the block, one or more pages of the block remain unwritten. Relatedly, a “closed” or “full” block can refer to a block in which all of the pages have associated memory cells that have been programmed.

In some memory sub-systems, the memory sub-system controller implements a block usage policy that closes a block after a certain triggering event (e.g., a threshold amount of read disturb has been detected at the block). Read disturb (RD) is the result of continually reading from memory cells without intervening erase operations, causing other memory cells on other nearby wordlines to change over time. The memory cells of each wordline of the memory device can handle a certain number of consecutive read operations before the memory cells are no longer able to reliably retrieve the data, reaching an RD capability limit (e.g., a threshold number of read operations, at which point retrieved data is no longer reliable). In some examples, RD capability can reduce as the program/erase cycle (PEC) of the memory device increases. In some examples, RD capability can be higher for full blocks than partial blocks. Also, RD capability for certain types of NAND devices can be higher than certain other types. If too many read operations are performed on the memory cells of a given wordline, data stored at memory cells of nearby or adjacent wordlines of the memory device can become corrupted or incorrectly stored at the memory cell. This can result in a higher error rate of the data stored at the memory cells and can increase the use of an error detection and correction operation for subsequent operations (e.g., read and/or write) performed on the memory cells. The increased use of error detection and correction operations can result in a reduction of the performance of a memory sub-system. In addition, as the error rate for a memory cell or block continues to increase, it may even surpass the error correction capabilities of the memory sub-system, leading to an irreparable loss of data. Furthermore, as more resources of the memory sub-system are used to perform error detection and correction operations, fewer resources can be used to perform other read operations or write operations. In order to eliminate the risk of data loss, read operations on the memory device are to be managed such that RD capability limits are not exceeded. In some cases, the memory sub-system can perform a data integrity check (also referred to herein as a “scan” or “scan operation”) to verify that the data stored at the block has errors within an acceptable limit (e.g., below the RD capability limit, etc.) defined for the memory sub-system. During the data integrity check, one or more reliability statistics are determined for data stored at the block by performing a read operation. One example of a reliability statistic is raw bit error rate (RBER). The RBER corresponds to a number of bit errors per sample size (e.g., per page or per codeword) that the data stored at the block experiences. If the reliability statistic indicates a high error rate associated with data stored at the block due, at least in part, to read disturb, then the data stored at the block can be relocated to a new block of the memory sub-system (also referred to herein as “folding”). The folding of the data stored at the block to the other block can include writing the data to the other block to refresh the data stored by the memory sub-system. This can be done to negate the effects of read disturb associated with the data and to erase the data at the block. In some implementations, the memory sub-system controller can then perform an erase operation to erase the block from which the data was written (e.g., the block associated with the high error rate).

However, as the storage capacity of memory devices becomes increasingly important, closing partial blocks can cause a waste of the remaining wordlines of the partial blocks that have not been programmed. More specifically, closing partial blocks can lead to a reduction in the total bytes written to the partial blocks before the partial blocks are closed. In addition, erasing data stored at a closed partial block can cause the remaining wordlines that have not been programmed to be double erased (e.g., the remaining wordlines are already empty because they have not been programmed with any data, so performing an erase operation on the empty wordlines will be erasing already empty wordlines). In turn, this increases the number of PECs that the memory device undergoes, which can lead to a reduced read window budget (RWB) margin and reduced RD capability of the memory device, as discussed above.

Aspects of the present disclosure address the above and other issues by implementing a block reopening protocol in a memory sub-system so that partial blocks can be reopened after being closed and can thus be used for additional programming operations. In some embodiments, a memory sub-system controller can identify a closed block of a memory device in the memory sub-system. The memory sub-system controller can perform a data integrity scan on the block in order to verify that the data stored at the block has errors within an acceptable limit. For example, the memory sub-system controller can perform the data integrity scan to determine one or more reliability statistics, such as the RBER of the block. If the one or more reliability statistics indicates an acceptable error rate associated with data stored at the block (e.g., an RBER that is below a predefined threshold level), then the memory sub-system controller can group the block with a set of blocks, where each block of the set of blocks has one or more reliability statistics that indicates an acceptable error rate associated with data stored at the respective block. Each block of the set of blocks can be used as an open block, such that the memory sub-system controller can send a programming command (e.g., a read command, write command, etc.) to program one or more wordlines of the block, where the one or more wordlines are adjacent to the last programmed wordline of the block before the block was closed. If the one or more reliability statistics indicates a high error rate associated with data stored at the block (e.g., an RBER that is greater than or equal to the predefined threshold level), then the memory sub-system controller can group the block with another set of blocks, where each block of the set of blocks has one or more reliability statistics that indicates a high error rate associated with data stored at the respective block. The memory sub-system controller can send an erase command to erase each block within this set of blocks.

Advantages of the approaches described herein include improved performance in the memory sub-system. By reopening closed partial blocks, there can be a reduction in wasted capacity from closing partial blocks with remaining wordlines that are still available to be programmed. Thus, there can be an increase in storage capacity for the memory sub-system. Further, there can be an increase in the total bytes written to blocks by being able to program memory cells along more wordlines of blocks. In addition, as discussed above, aspects of this disclosure can help to avoid the double erase effect on partial blocks being erased, since the majority of partial blocks will be able to be programmed before the blocks are closed and erased.

FIG. 1A illustrates an example computing system 100 that includes a memory sub-system 110 in accordance with some embodiments of the present disclosure. The memory sub-system 110 can include media, such as one or more volatile memory devices (e.g., memory device 140), one or more non-volatile memory devices (e.g., one or more memory device(s) 130), or a combination of such.

A memory sub-system 110 can be a storage device, a memory module, or a hybrid of a storage device and memory module. Examples of a storage device include a solid-state drive (SSD), a flash drive, a universal serial bus (USB) flash drive, an embedded Multi-Media Controller (eMMC) drive, a Universal Flash Storage (UFS) drive, a secure digital (SD) card, and a hard disk drive (HDD). Examples of memory modules include a dual in-line memory module (DIMM), a small outline DIMM (SO-DIMM), and various types of non-volatile dual in-line memory modules (NVDIMMs).

The computing system 100 can be a computing device such as a desktop computer, laptop computer, network server, mobile device, a vehicle (e.g., airplane, drone, train, automobile, or other conveyance), Internet of Things (IoT) enabled device, embedded computer (e.g., one included in a vehicle, industrial equipment, or a networked commercial device), or such computing device that includes memory and a processing device.

The computing system 100 can include a host system 120 that is coupled to one or more memory sub-systems 110. In some embodiments, the host system 120 is coupled to different types of memory sub-system 110. FIG. 1A illustrates one example of a host system 120 coupled to one memory sub-system 110. As used herein, “coupled to” or “coupled with” generally refers to a connection between components, which can be an indirect communicative connection or direct communicative connection (e.g., without intervening components), whether wired or wireless, including connections such as electrical, optical, magnetic, etc.

The host system 120 can include a processor chipset and a software stack executed by the processor chipset. The processor chipset can include one or more cores, one or more caches, a memory controller (e.g., NVDIMM controller), and a storage protocol controller (e.g., PCle controller, SATA controller, CXL controller). The host system 120 uses the memory sub-system 110, for example, to write data to the memory sub-system 110 and read data from the memory sub-system 110.

The host system 120 can be coupled to the memory sub-system 110 via a physical host interface. Examples of a physical host interface include, but are not limited to, a serial advanced technology attachment (SATA) interface, a compute express link (CXL) interface, a peripheral component interconnect express (PCle) interface, universal serial bus (USB) interface, Fibre Channel, Serial Attached SCSI (SAS), a double data rate (DDR) memory bus, Small Computer System Interface (SCSI), a dual in-line memory module (DIMM) interface (e.g., DIMM socket interface that supports Double Data Rate (DDR)), etc. The physical host interface can be used to transmit data between the host system 120 and the memory sub-system 110. The host system 120 can further utilize an NVM Express (NVMe) interface to access the memory components (e.g., the one or more memory device(s) 130) when the memory sub-system 110 is coupled with the host system 120 by the physical host interface (e.g., PCle interface or CXL bus). The physical host interface can provide an interface for passing control, address, data, and other signals between the memory sub-system 110 and the host system 120. FIG. 1A illustrates a memory sub-system 110 as an example. In general, the host system 120 can access multiple memory sub-systems via a same communication connection, multiple separate communication connections, and/or a combination of communication connections.

The memory devices 130, 140 can include any combination of the different types of non-volatile memory devices and/or volatile memory devices. The volatile memory devices (e.g., memory device 140) can be, but are not limited to, random access memory (RAM), such as dynamic random access memory (DRAM) and synchronous dynamic random access memory (SDRAM).

Some examples of non-volatile memory devices (e.g., memory device(s) 130) include negative-and (NAND) type flash memory and write-in-place memory, such as three-dimensional cross-point (“3D cross-point”) memory. A cross-point array of non-volatile memory can perform bit storage based on a change of bulk resistance, in conjunction with a stackable cross-gridded data access array. Additionally, in contrast to many flash-based memories, cross-point non-volatile memory can perform a write in-place operation, where a non-volatile memory cell can be programmed without the non-volatile memory cell being previously erased. NAND type flash memory includes, for example, two-dimensional NAND (2D NAND) and three-dimensional NAND (3D NAND).

Each of the memory device(s) 130 can include one or more arrays of memory cells. One type of memory cell, for example, single level cells (SLC) can store one bit per cell. Other types of memory cells, such as multi-level cells (MLCs), triple level cells (TLCs), and quad-level cells (QLCs), can store multiple bits per cell. In some embodiments, each of the memory devices 130 can include one or more arrays of memory cells such as SLCs, MLCs, TLCs, QLCs, or any combination of such. In some embodiments, a particular memory device can include an SLC portion, and an MLC portion, a TLC portion, or a QLC portion of memory cells. The memory cells of the memory devices 130 can be grouped as pages that can refer to a logical unit of the memory device used to store data. With some types of memory (e.g., NAND), pages can be grouped to form blocks.

Although non-volatile memory components such as a 3D cross-point array of non-volatile memory cells and NAND type flash memory (e.g., 2D NAND, 3D NAND) are described, the memory device 130 can be based on any other type of non-volatile memory, such as read-only memory (ROM), phase change memory (PCM), self-selecting memory, other chalcogenide based memories, ferroelectric transistor random-access memory (FeTRAM), ferroelectric random access memory (FeRAM), magneto random access memory (MRAM), Spin Transfer Torque (STT)-MRAM, conductive bridging RAM (CBRAM), resistive random access memory (RRAM), oxide based RRAM (OxRAM), negative-or (NOR) flash memory, electrically erasable programmable read-only memory (EEPROM).

A memory sub-system controller 115 (or controller 115 for simplicity) can communicate with the memory device(s) 130 to perform operations such as reading data, writing data, or erasing data at the memory devices 130 and other such operations. The memory sub-system controller 115 can include hardware such as one or more integrated circuits and/or discrete components, a buffer memory, or a combination thereof. The hardware can include a digital circuitry with dedicated (i.e., hard-coded) logic to perform the operations described herein. The memory sub-system controller 115 can be a microcontroller, special purpose logic circuitry (e.g., a field programmable gate array (FPGA), an application specific integrated circuit (ASIC), etc.), or other suitable processor.

The memory sub-system controller 115 can include a processor 117 (e.g., a processing device) configured to execute instructions stored in a local memory 119. In the illustrated example, the local memory 119 of the memory sub-system controller 115 includes an embedded memory configured to store instructions for performing various processes, operations, logic flows, and routines that control operation of the memory sub-system 110, including handling communications between the memory sub-system 110 and the host system 120.

In some embodiments, the local memory 119 can include memory registers storing memory pointers, fetched data, etc. The local memory 119 can also include read-only memory (ROM) for storing micro-code. While the example memory sub-system 110 in FIG. 1A has been illustrated as including the memory sub-system controller 115, in another embodiment of the present disclosure, a memory sub-system 110 does not include a memory sub-system controller 115, and can instead rely upon external control (e.g., provided by an external host, or by a processor or controller separate from the memory sub-system).

In general, the memory sub-system controller 115 can receive commands or operations from the host system 120 and can convert the commands or operations into instructions or appropriate commands to achieve the desired access to the memory device(s) 130. The memory sub-system controller 115 can be responsible for other operations such as wear leveling operations, garbage collection operations, error detection and error-correcting code (ECC) operations, encryption operations, caching operations, and address translations between a logical address (e.g., logical block address (LBA), namespace) and a physical address (e.g., physical block address) that are associated with the memory device(s) 130. The memory sub-system controller 115 can further include host interface circuitry to communicate with the host system 120 via the physical host interface. The host interface circuitry can convert the commands received from the host system into command instructions to access the memory device(s) 130 as well as convert responses associated with the memory device(s) 130 into information for the host system 120.

The memory sub-system 110 can also include additional circuitry or components that are not illustrated. In some embodiments, the memory sub-system 110 can include a cache or buffer (e.g., DRAM) and address circuitry (e.g., a row decoder and a column decoder) that can receive an address from the memory sub-system controller 115 and decode the address to access the memory device(s) 130.

In some embodiments, the memory device(s) 130 include local media controllers 135 that operate in conjunction with memory sub-system controller 115 to execute operations on one or more memory cells of the memory device(s) 130. An external controller (e.g., memory sub-system controller 115) can externally manage the memory device 130 (e.g., perform media management operations on the memory device(s) 130). In some embodiments, a memory device 130 is a managed memory device, which is a raw memory device (e.g., memory array 104) having control logic (e.g., local controller 135) for media management within the same memory device package. An example of a managed memory device is a managed NAND (MNAND) device. Memory device(s) 130, for example, can each represent a single die having some control logic (e.g., local media controller 135) embodied thereon. In some embodiments, one or more components of memory sub-system 110 can be omitted.

In one embodiment, the memory sub-system 110 includes a block reopening management component 113. In some embodiments, the block reopening management component 113 can identify a closed block of a memory device in the memory sub-system. The block reopening management component 113 can perform a data integrity scan on the block in order to verify that the data stored at the block has errors within an acceptable limit. For example, the block reopening management component 113 can perform the data integrity scan to determine one or more reliability statistics, such as the RBER of the block. If the one or more reliability statistics indicates an acceptable error rate associated with data stored at the block, then the block reopening management component 113 can group the block with a set of blocks, where each block of the set of blocks has one or more reliability statistics that indicates an acceptable error rate associated with data stored at the respective block. Each block of the set of blocks can be used as an open block, such that the memory sub-system controller can send a programming command (e.g., a read command, write command, etc.) to program one or more wordlines of the block, where the one or more wordlines are adjacent to the last programmed wordline of the block before the block was closed. If the one or more reliability statistics indicates a high error rate associated with data stored at the block, then the block reopening management component 113 can group the block with another set of blocks, where each block of the set of blocks has one or more reliability statistics that indicates a high error rate associated with data stored at the respective block. The block reopening management component 113 can send an erase command to erase each block within this set of blocks. Further details with regards to the operations of block reopening management component 113 are described below.

FIG. 1B is a simplified block diagram of a first apparatus, in the form of a memory device 130, in communication with a second apparatus, in the form of a memory sub-system controller 115 of a memory sub-system (e.g., memory sub-system 110 of FIG. 1A), according to an embodiment. Some examples of electronic systems include personal computers, personal digital assistants (PDAs), digital cameras, digital media players, digital recorders, games, appliances, vehicles, wireless devices, mobile telephones and the like. The memory sub-system controller 115 (e.g., a controller external to the memory device 130), may be a memory controller or other external host device. In some embodiments, memory sub-system controller 115 includes block reopening management component 113.

Memory device 130 includes an array of memory cells 104 logically arranged in rows and columns. Memory cells of a logical row are typically connected to the same access line (e.g., a word), while memory cells of a logical column are typically selectively connected to the same data line (e.g., a bit line). A single access line may be associated with more than one logical row of memory cells and a single data line may be associated with more than one logical column. Memory cells (not shown in FIG. 1B) of at least a portion of array of memory cells 104 are capable of being programmed to one of at least two target data states.

Row decode circuitry 108 and column decode circuitry 109 are provided to decode address signals. Address signals are received and decoded to access the array of memory cells 104. Memory device 130 also includes input/output (I/O) control circuitry 160 to manage input of commands, addresses, and data to the memory device 130 as well as output of data and status information from the memory device 130. An address register 114 is in communication with I/O control circuitry 160 and row decode circuitry 108 and column decode circuitry 109 to latch the address signals prior to decoding. A command register 124 is in communication with I/O control circuitry 160 and local media controller 135 to latch incoming commands.

A controller (e.g., the local media controller 135 internal to the memory device 130) controls access to the array of memory cells 104 in response to the commands and generates status information for the external memory sub-system controller 115, i.e., the local media controller 135 is configured to perform access operations (e.g., read operations, programming operations and/or erase operations) on the array of memory cells 104. The local media controller 135 is in communication with row decode circuitry 108 and column decode circuitry 109 to control the row decode circuitry 108 and column decode circuitry 109 in response to the addresses.

The local media controller 135 is also in communication with a cache register 172. Cache register 172 latches data, either incoming or outgoing, as directed by the local media controller 135 to temporarily store data while the array of memory cells 104 is busy writing or reading, respectively, other data. During a program operation (e.g., write operation), data may be passed from the cache register 172 to the data register 170 for transfer to the array of memory cells 104; then new data may be latched in the cache register 172 from the I/O control circuitry 160. During a read operation, data may be passed from the cache register 172 to the I/O control circuitry 160 for output to the memory sub-system controller 115; then new data may be passed from the data register 170 to the cache register 172. The cache register 172 and/or the data register 170 may form (e.g., may form a portion of) a page buffer of the memory device 130. A page buffer may further include sensing devices (not shown in FIG. 1B) to sense a data state of a memory cell of the array of memory cells 104, e.g., by sensing a state of a data line connected to that memory cell. A status register 122 may be in communication with I/O control circuitry 160 and the local memory controller 135 to latch the status information for output to the memory sub-system controller 115.

Memory device 130 receives control signals at the memory sub-system controller 115 from the local media controller 135 over a control link 132. For example, the control signals can include a chip enable signal CE#, a command latch enable signal CLE, an address latch enable signal ALE, a write enable signal WE#, a read enable signal RE#, and a write protect signal WP#. Additional or alternative control signals (not shown) may be further received over control link 132 depending upon the nature of the memory device 130. In some embodiments, memory device 130 receives command signals (which represent commands), address signals (which represent addresses), and data signals (which represent data) from the memory sub-system controller 115 over a multiplexed input/output (I/O) bus 134 and outputs data to the memory sub-system controller 115 over I/O bus 134.

For example, the commands may be received over input/output (I/O) pins [7:0] of I/O bus 134 at I/O control circuitry 160 and may then be written into command register 124. The addresses may be received over input/output (I/O) pins [7:0] of I/O bus 134 at I/O control circuitry 160 and may then be written into address register 114. The data may be received over input/output (I/O) pins [7:0] for an 8-bit device or input/output (I/O) pins [15:0] for a 16-bit device at I/O control circuitry 160 and then may be written into cache register 172. The data may be subsequently written into data register 170 for programming the array of memory cells 104.

In an embodiment, cache register 172 may be omitted, and the data may be written directly into data register 170. Data may also be output over input/output (I/O) pins [7:0] for an 8-bit device or input/output (I/O) pins [15:0] for a 16-bit device. Although reference may be made to I/O pins, they may include any conductive node providing for electrical connection to the memory device 130 by an external device (e.g., the memory sub-system controller 115), such as conductive pads or conductive bumps as are commonly used.

It will be appreciated by those skilled in the art that additional circuitry and signals can be provided, and that the memory device 130 of FIG. 1B has been simplified. It should be recognized that the functionality of the various block components described with reference to FIG. 1B may not necessarily be segregated to distinct components or component portions of an integrated circuit device. For example, a single component or component portion of an integrated circuit device could be adapted to perform the functionality of more than one block component of FIG. 1B. Alternatively, one or more components or component portions of an integrated circuit device could be combined to perform the functionality of a single block component of FIG. 1B. Additionally, while specific I/O pins are described in accordance with popular conventions for receipt and output of the various signals, it is noted that other combinations or numbers of I/O pins (or other I/O node structures) may be used in the various embodiments.

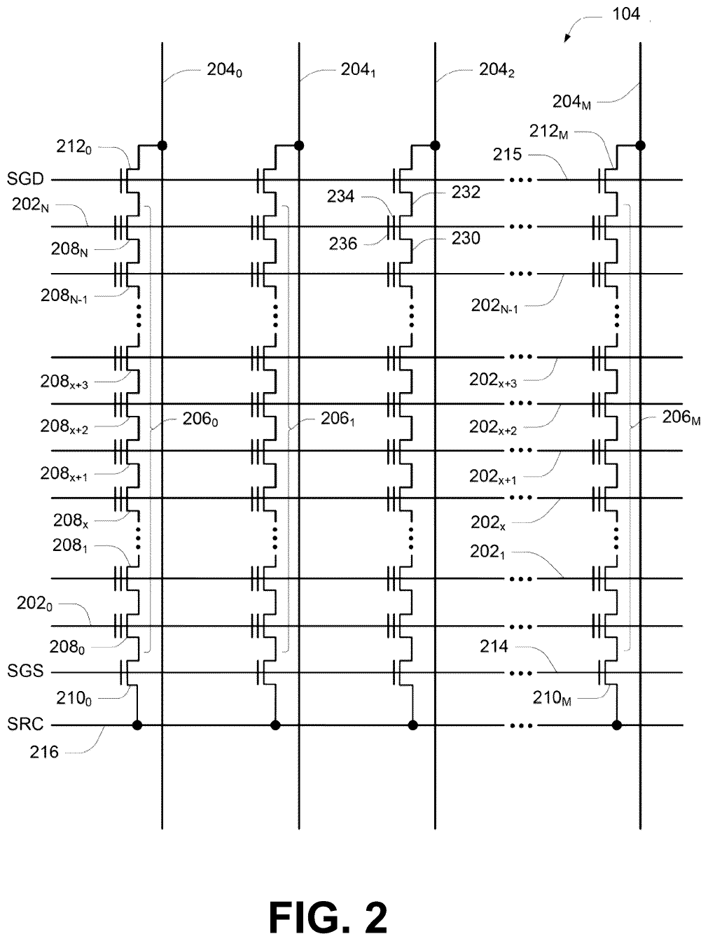

FIG. 2 is a schematic of portions of an array of memory cells 104, such as a NAND memory array, as could be used in a memory of the type described with reference to FIG. 1B according to an embodiment. Memory array 104 includes access lines, such as wordlines 202₀ to 202_{N,} and data lines, such as bit lines 204₀ to 204_{M}. The wordlines 202 can be connected to global access lines (e.g., global wordlines), not shown in FIG. 2, in a many-to-one relationship. For some embodiments, memory array 104 can be formed over a semiconductor that, for example, can be conductively doped to have a conductivity type, such as a p-type conductivity, e.g., to form a p-well, or an n-type conductivity, e.g., to form an n-well.

Memory array 104 can be arranged in rows (each corresponding to a wordline 202) and columns (each corresponding to a bit line 204). Each column can include a string of series-connected memory cells (e.g., non-volatile memory cells), such as one of NAND strings 206₀ to 206_{M}. Each NAND string 206 can be connected (e.g., selectively connected) to a common source (SRC) 216 and can include memory cells 208₀ to 208_{N}. The memory cells 208 can represent non-volatile memory cells for storage of data. The memory cells 208 of each NAND string 206 can be connected in series between a select gate 210 (e.g., a field-effect transistor), such as one of the select gates 210₀ to 210_{M} (e.g., that can be source select transistors, commonly referred to as select gate source), and a select gate 212 (e.g., a field-effect transistor), such as one of the select gates 212₀ to 212_{M} (e.g., that can be drain select transistors, commonly referred to as select gate drain). Select gates 210₀ to 210_{M} can be commonly connected to a select line 214, such as a source select line (SGS), and select gates 212₀ to 212_{M} can be commonly connected to a select line 215, such as a drain select line (SGD). Although depicted as traditional field-effect transistors, the select gates 210 and 212 can utilize a structure similar to (e.g., the same as) the memory cells 208. The select gates 210 and 212 can represent a number of select gates connected in series, with each select gate in series configured to receive a same or independent control signal.

A source of each select gate 210 can be connected to common source 216. The drain of each select gate 210 can be connected to a memory cell 208₀ of the corresponding NAND string 206. For example, the drain of select gate 210₀ can be connected to memory cell 208₀ of the corresponding NAND string 206₀. Therefore, each select gate 210 can be configured to selectively connect a corresponding NAND string 206 to the common source 216. A control gate of each select gate 210 can be connected to the select line 214.

The drain of each select gate 212 can be connected to the bit line 204 for the corresponding NAND string 206. For example, the drain of select gate 212₀ can be connected to the bit line 204₀ for the corresponding NAND string 206₀. The source of each select gate 212 can be connected to a memory cell 208_{N} of the corresponding NAND string 206. For example, the source of select gate 212₀ can be connected to memory cell 208_{N} of the corresponding NAND string 206₀. Therefore, each select gate 212 can be configured to selectively connect a corresponding NAND string 206 to the corresponding bit line 204. A control gate of each select gate 212 can be connected to select line 215.

The memory array 104 in FIG. 2 can be a quasi-two-dimensional memory array and can have a generally planar structure, e.g., where the common source 216, NAND strings 206 and bit lines 204 extend in substantially parallel planes. Alternatively, the memory array 104 in FIG. 2 can be a three-dimensional memory array, e.g., where NAND strings 206 can extend substantially perpendicular to a plane containing the common source 216 and to a plane containing the bit lines 204 that can be substantially parallel to the plane containing the common source 216.

Typical construction of memory cells 208 includes a data-storage structure 234 (e.g., a floating gate, charge trap, and the like) that can determine a data state of the memory cell (e.g., through changes in threshold voltage), and a control gate 236, as shown in FIG. 2. The data-storage structure 234 can include both conductive and dielectric structures while the control gate 236 is generally formed of one or more conductive materials. In some cases, memory cells 208 can further have a defined source/drain (e.g., source) 230 and a defined source/drain (e.g., drain) 232. The memory cells 208 have their control gates 236 connected to (and in some cases form) a wordline 202.

A column of the memory cells 208 can be a NAND string 206 or a number of NAND strings 206 selectively connected to a given bit line 204. A row of the memory cells 208 can be memory cells 208 commonly connected to a given wordline 202. A row of memory cells 208 can, but need not, include all the memory cells 208 commonly connected to a given wordline 202. Rows of the memory cells 208 can often be divided into one or more groups of physical pages of memory cells 208, and physical pages of the memory cells 208 often include every other memory cell 208 commonly connected to a given wordline 202. For example, the memory cells 208 commonly connected to wordline 202_{N} and selectively connected to even bit lines 204 (e.g., bit lines 204₀, 204₂, 204₄, etc.) can be one physical page of the memory cells 208 (e.g., even memory cells) while memory cells 208 commonly connected to wordline 202_{N} and selectively connected to odd bit lines 204 (e.g., bit lines 204₁, 204₃, 204₅, etc.) can be another physical page of the memory cells 208 (e.g., odd memory cells).

Although bit lines 204₃-204₅ are not explicitly depicted in FIG. 2, it is apparent from the figure that the bit lines 204 of the array of memory cells 104 can be numbered consecutively from bit line 204₀ to bit line 204_{M}. Other groupings of the memory cells 208 commonly connected to a given wordline 202 can also define a physical page of memory cells 208. For certain memory devices, all memory cells commonly connected to a given wordline can be deemed a physical page of memory cells. The portion of a physical page of memory cells (which, in some embodiments, could still be the entire row) that is read during a single read operation or programmed during a single programming operation (e.g., an upper or lower page of memory cells) can be deemed a logical page of memory cells. A block of memory cells can include those memory cells that are configured to be erased together, such as all memory cells connected to wordlines 202₀-202_{N} (e.g., all NAND strings 206 sharing common wordlines 202). Unless expressly distinguished, a reference to a page of memory cells herein refers to the memory cells of a logical page of memory cells. Although the example of FIG. 2 is discussed in conjunction with NAND flash, the embodiments and concepts described herein are not limited to a particular array architecture or structure, and can include other structures (e.g., SONOS, phase change, ferroelectric, etc.) and other architectures (e.g., AND arrays, NOR arrays, etc.).

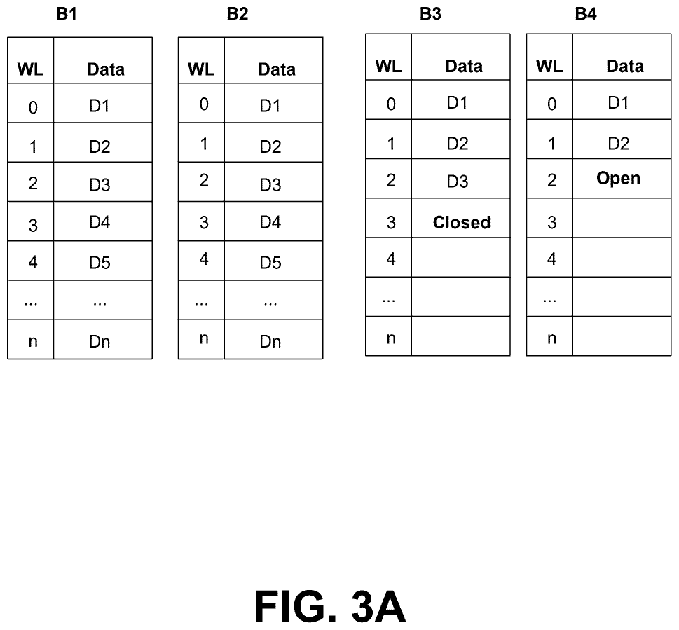

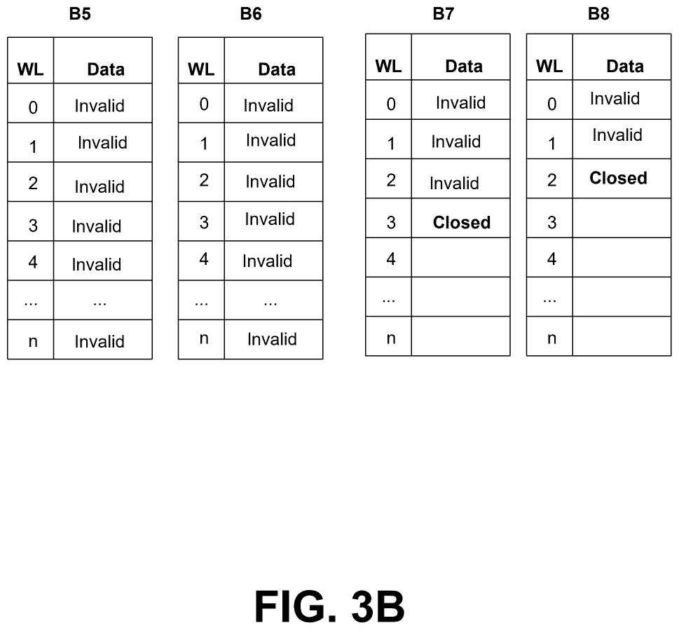

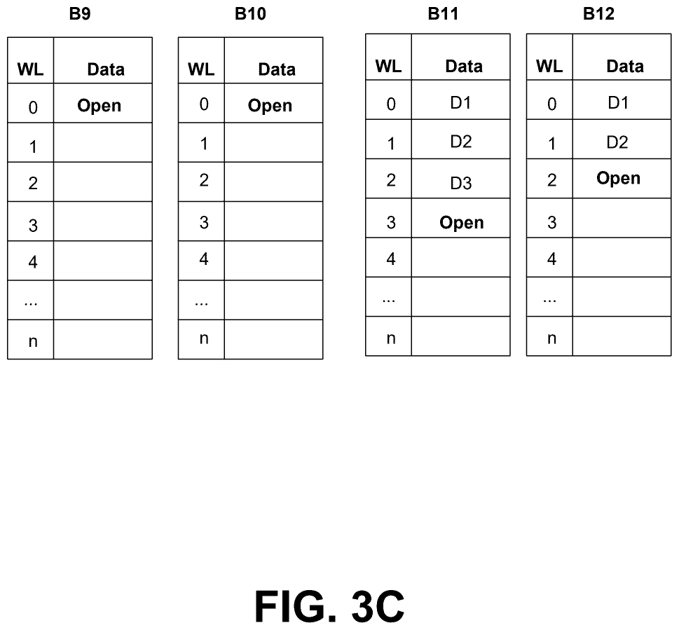

FIG. 3A is a diagram illustrating an example set of blocks of a memory device, in accordance with some embodiments of the present disclosure. As shown, each block includes a number of individual portions (e.g., wordlines), including wordline WL0 through wordline WLn. Each wordline can be associated with data that can be stored at a set of memory cells along each wordline. For example, block BI can have data D1 stored at a set of memory cells along wordline WL0, data D2 can be stored at a set of memory cells along wordline WL1, etc. As another example, block B2 can have data D1 stored at a set of memory cells along wordline WL0, data D2 can be stored at a set of memory cells along wordline WL1, etc. As shown, blocks B1 and B2 are “full” blocks (e.g., all wordlines of each block B1 and B2 have been programmed), as described herein. In another example, block B3 can have data D1 stored at a set of memory cells along wordline WL0, data D2 stored at a set of memory cells along wordline WL1, and data D3 stored at a set of memory cells along wordline 2. As shown, block B3 can have some remaining wordlines (e.g., wordline WL4 through wordline WLn) that have not been programmed with any data. Further, as shown, block B3 can be considered a “closed” partial block, where wordline WL2 is the last programmed wordline. In another example, block B4 can have data D1 stored at a set of memory cells along wordline WL0 and data D2 stored at a set of memory cells along wordline WL1. As shown, block B4 can have some remaining wordlines (e.g., wordline WL2 through wordline WLn) that have not been programmed with any data. Further, as shown, block B4 can be considered as an “open” partial block, where wordline WL1 is the last programmed wordline.

FIG. 3B is a diagram illustrating another example set of blocks of a memory device, in accordance with some embodiments of the present disclosure. As shown, each block includes a number of individual portions (e.g., wordlines), including wordline WL0 through wordline WLn. Each wordline can be associated with data that can be stored at a set of memory cells along each wordline. The set of blocks can include blocks that can be erased (e.g., the set of blocks can be a set of blocks for garbage collection). For example, block B5 can have data that is considered invalid stored at sets of memory cells along wordline WL0 through wordline WLn. As another example, block B6 can have data that is considered invalid stored at sets of memory cells along wordline WL0 through wordline WLn. As shown, blocks B5 and B6 are “full” blocks, as described herein. In another example, block B7 can have data that is considered invalid stored at sets of memory cells along wordline WL0 through wordline WL2. As shown, block B7 can have some remaining word lines (e.g., word line WL4 through word line WLn) that have not been programmed with any data. Further, as shown, block B7 can be considered a “closed” partial block, where wordline WL2 is the last programmed wordline. In another example, block B8 can have data that is considered invalid stored at sets of memory cells along wordline WL0 through wordline WL1. As shown, block B8 can have some remaining wordlines (e.g., wordline WL2 through wordline WLn) that have not been programmed with any data. Further, as shown, block B8 can be considered as a “closed” partial block, where wordline WL1 is the last programmed wordline.

FIG. 3C is a diagram illustrating another example set of blocks of a memory device, in accordance with some embodiments of the present disclosure. As shown, each block includes a number of individual portions (e.g., wordlines), including wordline WL0 through wordline WLn. Each wordline can be associated with data that can be stored at a set of memory cells along each wordline. The set of blocks can include blocks that are reopened. For example, block B9 can include wordline WL0 through wordline WLn that can be programmed with data. As another example, block B10 can include wordline WL0 through wordline WLn that can be programmed with data. In another example, block B11 can have a last programmed wordline at wordline WL2. Block B11 can be considered an “open” partial block, where wordline WL3 through wordline WLn can be programmed with data. In another example, block B12 can have a last programmed wordline at wordline WL1. Block B12 can be considered an “open” block, where wordline WL2 through wordline WLn can be programmed with data.

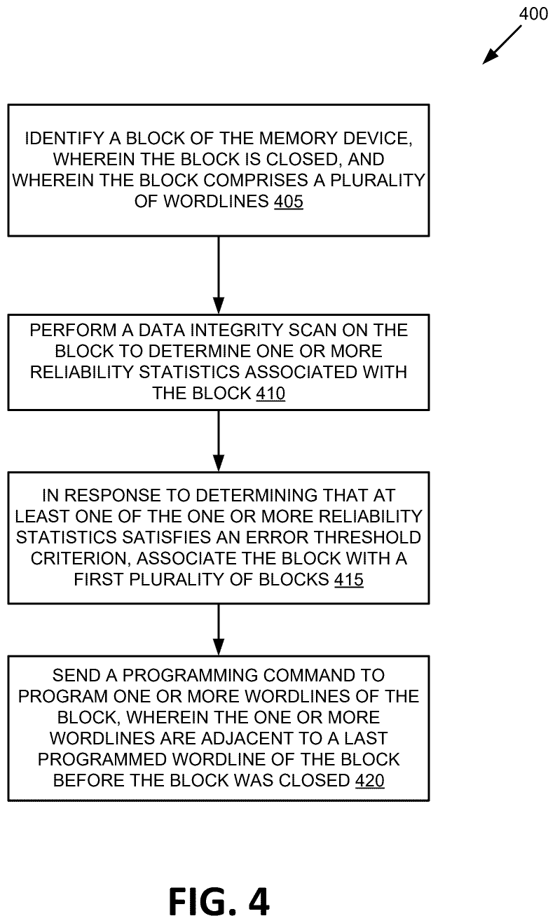

FIG. 4 is a flow diagram of an example method 400 of a block reopening protocol in a memory sub-system, in accordance with some embodiments of the present disclosure. The method 400 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some embodiments, the method 400 is performed by block reopening management component 113 of FIG. 1A. Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

At operation 405, processing logic (e.g., block reopening management component 113 or other portions of memory sub-system controller 115) identifies a block of a memory device (e.g., the memory device 130 of FIG. 1A). In some embodiments, the processing logic identifies a closed partial block, as described herein. In some embodiments, the block includes a set of wordlines. In some implementations, an example of a closed partial block is block B3 illustrated in FIG. 3A. In some embodiments, to identify the block, the processing logic can identify a block on which a folding operation is to be performed. For example, a folding operation can refer to data stored at the block being written to another block of the memory device. In some embodiments, the folding operation is to be performed on the block in response to a triggering event that indicates a high error rate (e.g., an RBER that is greater than or equal to a predefined threshold) associated with the block, as discussed herein. For example, the processing logic can determine that the block has a high error rate in response to performing a data integrity scan and/or another scan that can determine the error rate and/or RD capability of the block. For example, the scan can be a media scan, a read disturb scan, a read error handling scan, a wear leveling scan, an uncorrectable error correction code (UECC) scan, etc. In some embodiments, in response to identifying the block, the processing logic can determine that a last programmed wordline of the block (e.g., the last programmed wordline of the block before the block was closed) satisfies a threshold criterion (e.g., a wordline threshold criterion). For example, as illustrated in FIG. 3A, the last programmed wordline of block B3 is wordline WL2. The wordline threshold criterion can correspond to a threshold count of a maximum number of wordlines of the set of wordlines included in the block. For example, the processing logic can identify the maximum number of wordlines of the set of wordlines by maintaining a counter for the block and incrementing the counter for each wordline of the block. As an example, as illustrated in FIG. 3A, the maximum number of wordlines of block B3 is n, where n can represent an integer number, since there are up to n wordlines that can be programmed in block B3. In some embodiments, the threshold count can be set to a particular count that is less than or equal to the maximum number of wordlines of the block (e.g., during manufacturing and/or design of the memory device using offline testing and experimental data). In some embodiments, the threshold count can be 50% of the maximum number of wordlines.

In some embodiments, each wordline of the set of blocks included in the block can be mapped to an index number, where the index number represents an identifier of the count of the wordline in relation to the other wordlines of the set of wordlines included in the block. In some embodiments, determining that the last programmed wordline of the block satisfies the threshold criterion can include identifying the index number of the last programmed wordline. For example, the processing logic can identify the index number using metadata associated with the block, where the metadata identifies the index number for each wordline of the set of wordlines included in the block. As an example, as illustrated in FIG. 3A, the processing logic can identify that the index number of the last programmed wordline of block B3 is “2.” In response to identifying the index number of the last programmed wordline, the processing logic can determine, based on the index number, that the count of the last programmed wordline is less than the threshold count of the maximum number of wordlines. For example, in an example where the index number of the last programmed wordline is 2, the threshold count is set to 3, and the maximum number of wordlines is n (where n is equal to 10), the processing logic can compare the index number to the threshold count. In response to comparing the index number to the threshold count, the processing logic can determine that the index number is less than the threshold count. In response to determining that the index number is less than the threshold count, the processing logic can determine that the last programmed wordline of the block satisfies the wordline threshold criterion.

In some embodiments, the processing logic can determine that the last programmed wordline of the block does not satisfy the wordline threshold criterion. For example, determining that the last programmed wordline of the block does not satisfy the wordline threshold criterion can include determining that the index number is greater than the threshold count. In some embodiments, in response to determining that the last programmed wordline of the block does not satisfy the wordline threshold criterion, the processing logic can associate the block with a set of blocks (e.g., a first set of blocks), where each block of the set of blocks has one or more reliability statistics that does not satisfy another threshold criterion (e.g., an error threshold criterion). In some embodiments, the error threshold criterion can represent the RD capability limit, or be defined based on the RD capability limit, such as by considering a margin of RD capability. In some embodiments, the error threshold criterion can be defined based on various factors. In an example, the error threshold criterion can be modifiable. The error threshold criterion can be set or modified based on factors such as the particular type of memory device used, the life (e.g., age) of the memory device at the time the threshold is being used, etc. For example, the error threshold criterion corresponding to a first time can be different from the error threshold criterion corresponding to a second time, where the second time represents an end of life of the memory device. As the age of memory device reaches end of life status, the threshold for error can be different, such as lower than an earlier stage.

In some embodiments, the processing logic can retrieve the wordline threshold criterion, the threshold count, and/or error threshold criterion from a data structure associated with the block and/or the memory device. In some embodiments, the data structure can include one or more entries, where each entry includes an identifier of a block, an index number of each wordline of the set of wordlines included in the block, the wordline threshold criterion, the threshold count, and/or the error threshold criterion. In some embodiments, the data structure can be stored in the memory device 130.

At operation 410, the processing logic performs a data integrity scan on the block (e.g., the block identified at operation 405) to determine one or more reliability statistics associated with the block. For example, performing the data integrity scan can include performing an error detection operation on a set of memory cells of the block to determine the one or more reliability statistics. The one or more reliability statistics can include a raw bit error rate (RBER). The RBER corresponds to a number of bit errors per sample size (e.g., per page or per codeword) that the data stored at the block experiences. In an example, the RBER for a given block can be obtained by determining a maximum RBER from a set of sample memory cells addressable by a wordline of the given block.

At operation 415, the processing logic associates the block (e.g., the block identified at operation 405) with a set of blocks (e.g., a second set of blocks). In some embodiments, the processing logic associates the block with the second set of blocks in response to determining that at least one of the one or more reliability statistics (e.g., the one or more reliability statistics determined at operation 410) satisfies the error threshold criterion (e.g., the error threshold criterion described at operation 405). In some embodiments, the second set of blocks includes one or more blocks, where each block of the second set of blocks has one or more reliability statistics that satisfies the wordline threshold criterion. In some embodiments, in response to determining that the at least one of the one or more reliability statistics satisfies the error threshold criterion, the processing logic can identify the last programmed wordline of the block before the block was closed. The processing logic can store the last programmed wordline in an entry of a data structure associated with the memory device. In some embodiments, the data structure can include one or more entries, where each entry includes an identifier of a block and an identifier (e.g., the index number) of the identified last programmed wordline of the block. In some embodiments, the data structure can be stored in the memory device 130. In some embodiments, in response to associating the block with the second set of blocks, the processing logic can perform, at a predefined frequency, another data integrity scan to determine one or more updated reliability statistics associated with the block. In some embodiments, the predefined frequency can be set during manufacturing and/or design of the memory device using offline testing and experimental data.

In some embodiments, the processing logic can determine that the at least one of the one or more reliability statistics does not satisfy the error threshold criterion. In response to determining that the at least one of the one or more reliability statistics does not satisfy the threshold criterion, the processing logic can associate the block with the first set of blocks (e.g., the set of blocks discussed above, where each block of the set of blocks has one or more reliability statistics that does not satisfy the threshold criterion).

At operation 420, the processing logic sends a programming command (e.g., a read command, write command, etc.) to program one or more wordlines of the block (e.g., the block identified at operation 405). In some embodiments, the one or more wordlines are adjacent to a last programmed wordline of the block before the block was closed. In some embodiments, the processing logic can receive the programming command from a host system, e.g., the host system 120 of FIG. 1A.

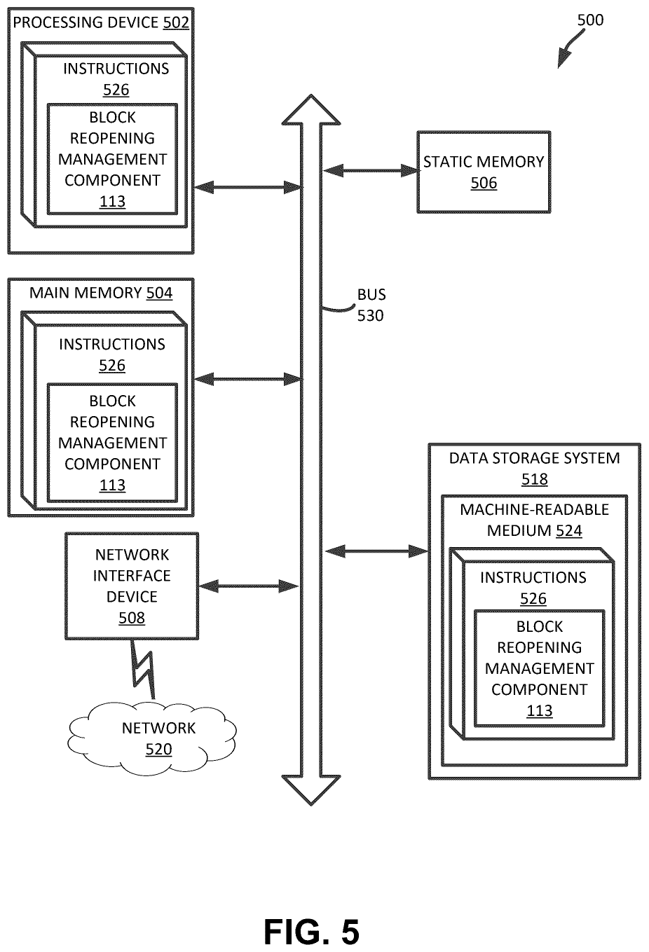

FIG. 5 illustrates an example machine of a computer system 500 within which a set of instructions, for causing the machine to perform any one or more of the methodologies discussed herein, can be executed. In some embodiments, the computer system 500 can correspond to a host system (e.g., the host system 120 of FIG. 1A) that includes, is coupled to, or utilizes a memory sub-system (e.g., the memory sub-system 110 of FIG. 1A) or can be used to perform the operations of a controller (e.g., to execute an operating system to perform operations corresponding to the block reopening management component 113 of FIG. 1A). In alternative embodiments, the machine can be connected (e.g., networked) to other machines in a LAN, an intranet, an extranet, and/or the Internet. The machine can operate in the capacity of a server or a client machine in client-server network environment, as a peer machine in a peer-to-peer (or distributed) network environment, or as a server or a client machine in a cloud computing infrastructure or environment.

The machine can be a personal computer (PC), a tablet PC, a set-top box (STB), a Personal Digital Assistant (PDA), a cellular telephone, a web appliance, a server, a network router, a switch or bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system 500 includes a processing device 502, a main memory 504 (e.g., read-only memory (ROM), flash memory, dynamic random access memory (DRAM) such as synchronous DRAM (SDRAM) or Rambus DRAM (RDRAM), etc.), a static memory 506 (e.g., flash memory, static random access memory (SRAM), etc.), and a data storage system 518, which communicate with each other via a bus 530.

Processing device 502 represents one or more general-purpose processing devices such as a microprocessor, a central processing unit, or the like. More particularly, the processing device can be a complex instruction set computing (CISC) microprocessor, reduced instruction set computing (RISC) microprocessor, very long instruction word (VLIW) microprocessor, or a processor implementing other instruction sets, or processors implementing a combination of instruction sets. Processing device 502 can also be one or more special-purpose processing devices such as an application specific integrated circuit (ASIC), a field programmable gate array (FPGA), a digital signal processor (DSP), network processor, or the like. The processing device 502 is configured to execute instructions 526 for performing the operations and steps discussed herein. The computer system 500 can further include a network interface device 508 to communicate over the network 520.

The data storage system 518 can include a non-transitory computer-readable storage medium 524 (also known as a machine-readable medium) on which is stored one or more sets of instructions 526 or software embodying any one or more of the methodologies or functions described herein. The instructions 526 can also reside, completely or at least partially, within the main memory 504 and/or within the processing device 502 during execution thereof by the computer system 500, the main memory 504 and the processing device 502 also constituting machine-readable storage media. The machine-readable storage medium 524, data storage system 518, and/or main memory 504 can correspond to the memory sub-system 110 of FIG. 1A.

In some embodiments, the instructions 526 include instructions to implement functionality corresponding to the block reopening management component 113 of FIG. 1A). While the machine-readable storage medium 524 is shown in an example embodiment to be a single medium, the term “machine-readable storage medium” should be taken to include a single medium or multiple media that store the one or more sets of instructions. The term “machine-readable storage medium” shall also be taken to include any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities. Usually, though not necessarily, these quantities take the form of electrical or magnetic signals capable of being stored, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. The present disclosure can refer to the action and processes of a computer system, or similar electronic computing device, that manipulates and transforms data represented as physical (electronic) quantities within the computer system's registers and memories into other data similarly represented as physical quantities within the computer system memories or registers or other such information storage systems.

The present disclosure also relates to an apparatus for performing the operations herein. This apparatus can be specially constructed for the intended purposes, or it can include a general purpose computer selectively activated or reconfigured by a computer program stored in the computer. Such a computer program can be stored in a computer readable storage medium, such as, but not limited to, any type of disk including floppy disks, optical disks, CD-ROMs, and magnetic-optical disks, read-only memories (ROMs), random access memories (RAMs), EPROMs, EEPROMs, magnetic or optical cards, or any type of media suitable for storing electronic instructions, each coupled to a computer system bus.

The algorithms and displays presented herein are not inherently related to any particular computer or other apparatus. Various general purpose systems can be used with programs in accordance with the teachings herein, or it can prove convenient to construct a more specialized apparatus to perform the method. The structure for a variety of these systems will appear as set forth in the description below. In addition, the present disclosure is not described with reference to any particular programming language. It will be appreciated that a variety of programming languages can be used to implement the teachings of the disclosure as described herein.

The present disclosure can be provided as a computer program product, or software, that can include a machine-readable medium having stored thereon instructions, which can be used to program a computer system (or other electronic devices) to perform a process according to the present disclosure. A machine-readable medium includes any mechanism for storing information in a form readable by a machine (e.g., a computer). In some embodiments, a machine-readable (e.g., computer-readable) medium includes a machine (e.g., a computer) readable storage medium such as a read only memory (“ROM”), random access memory (“RAM”), magnetic disk storage media, optical storage media, flash memory components, etc.

In the foregoing specification, embodiments of the disclosure have been described with reference to specific example embodiments thereof. It will be evident that various modifications can be made thereto without departing from the broader spirit and scope of embodiments of the disclosure as set forth in the following claims. The specification and drawings are, accordingly, to be regarded in an illustrative sense rather than a restrictive sense.

What is claimed is:

1. A system comprising:
a memory device; and
a processing device, operatively coupled with the memory device, to perform operations comprising:
identifying a block of the memory device, wherein the block is closed, and wherein the block comprises a plurality of wordlines;
performing a data integrity scan on the block to determine one or more reliability statistics associated with the block;
in response to determining that at least one of the one or more reliability statistics satisfies a first threshold criterion, associating the block with a first plurality of blocks, wherein each block of the first plurality of blocks is associated with at least one or more reliability statistics that satisfies the first threshold criterion; and
sending a programming command to program one or more wordlines of the block, wherein the one or more wordlines are adjacent to a last programmed wordline of the block before the block was closed.

2. The system of claim 1, wherein the processing device is to perform operations further comprising:
in response to identifying the block, determining that the last programmed wordline of the block satisfies a second threshold criterion, wherein the second threshold criterion corresponds to a threshold count of the plurality of wordlines.

3. The system of claim 2, wherein the processing device is to perform operations further comprising:
in response to determining that the last programmed wordline of the block does not satisfy the second threshold criterion, associating the block with a second plurality of blocks, wherein one or more blocks of the second plurality of blocks is associated with at least one or more reliability statistics that do not satisfy the first threshold criterion.

4. The system of claim 1, wherein the processing device is to perform operations further comprising:
in response to determining that the at least one of the one or more reliability statistics does not satisfy the first threshold criterion, associating the block with a second plurality of blocks, wherein one or more blocks of the second plurality of blocks is associated with at least one or more reliability statistics that do not satisfy the first threshold criterion.

5. The system of claim 1, wherein the processing device is to perform operations further comprising:
in response to determining that the at least one of the one or more reliability statistics satisfies the first threshold criterion, identifying the last programmed wordline of the block before the block was closed; and
store, in an entry of a data structure associated with the memory device, the last programmed wordline of the block before the block was closed.

6. The system of claim 1, wherein the processing device is to perform operations further comprising:
in response to associating the block with the first plurality of blocks, performing, at a predefined frequency, another data integrity scan on the block to determine the one or more reliability statistics associated with the block.

7. The system of claim 1, wherein, to identify the block of the memory device, the processing device is to perform operations further comprising:
identifying that the block is associated with a folding operation, wherein data stored at the block is written to another block of the memory device.

8. A method comprising:
identifying a block of a memory device, wherein the block is closed, and wherein the block comprises a plurality of wordlines;
performing a data integrity scan on the block to determine one or more reliability statistics associated with the block;
in response to determining that at least one of the one or more reliability statistics satisfies a first threshold criterion, associating the block with a first plurality of blocks, wherein each block of the first plurality of blocks is associated with at least one or more reliability statistics that satisfies the first threshold criterion; and
sending a programming command to program one or more wordlines of the block, wherein the one or more wordlines are adjacent to a last programmed wordline of the block before the block was closed.

9. The method of claim 8, further comprising:
in response to identifying the block, determining that the last programmed wordline of the block satisfies a second threshold criterion, wherein the second threshold criterion corresponds to a threshold count of the plurality of wordlines.

10. The method of claim 9, further comprising:
in response to determining that the last programmed wordline of the block does not satisfy the second threshold criterion, associating the block with a second plurality of blocks, wherein one or more blocks of the second plurality of blocks is associated with at least one or more reliability statistics that do not satisfy the first threshold criterion.

11. The method of claim 8, further comprising:
in response to determining that the at least one of the one or more reliability statistics does not satisfy the first threshold criterion, associating the block with a second plurality of blocks, wherein one or more blocks of the second plurality of blocks is associated with at least one or more reliability statistics that do not satisfy the first threshold criterion.

12. The method of claim 8, further comprising:
in response to determining that the at least one of the one or more reliability statistics satisfies the first threshold criterion, identifying the last programmed wordline of the block before the block was closed; and
store, in an entry of a data structure associated with the memory device, the last programmed wordline of the block before the block was closed.

13. The method of claim 8, further comprising:
in response to associating the block with the first plurality of blocks, performing, at a predefined frequency, another data integrity scan on the block to determine the one or more reliability statistics associated with the block.

14. The method of claim 8, wherein identifying the block of the memory device further comprises:
identifying that the block is associated with a folding operation, wherein data stored at the block is written to another block of the memory device.

15. A non-transitory computer-readable storage medium comprising instructions that, when executed by a processing device, cause the processing device to perform operations comprising:
identifying a block of a memory device, wherein the block is closed, and wherein the block comprises a plurality of wordlines;
performing a data integrity scan on the block to determine one or more reliability statistics associated with the block;
in response to determining that at least one of the one or more reliability statistics satisfies a first threshold criterion, associating the block with a first plurality of blocks, wherein each block of the first plurality of blocks is associated with at least one or more reliability statistics that satisfies the first threshold criterion; and
sending a programming command to program one or more wordlines of the block, wherein the one or more wordlines are adjacent to a last programmed wordline of the block before the block was closed.

16. The non-transitory computer-readable storage medium of claim 15, wherein the instructions cause the processing device to perform operations further comprising:
in response to identifying the block, determining that the last programmed wordline of the block satisfies a second threshold criterion, wherein the second threshold criterion corresponds to a threshold count of the plurality of wordlines.

17. The non-transitory computer-readable storage medium of claim 16, wherein the instructions cause the processing device to perform operations further comprising:
in response to determining that the last programmed wordline of the block does not satisfy the second threshold criterion, associating the block with a second plurality of blocks, wherein one or more blocks of the second plurality of blocks is associated with at least one or more reliability statistics that do not satisfy the first threshold criterion.

18. The non-transitory computer-readable storage medium of claim 15, wherein the instructions cause the processing device to perform operations further comprising:
in response to determining that the at least one of the one or more reliability statistics does not satisfy the first threshold criterion, associating the block with a second plurality of blocks, wherein one or more blocks of the second plurality of blocks is associated with at least one or more reliability statistics that do not satisfy the first threshold criterion.

19. The non-transitory computer-readable storage medium of claim 15, wherein the instructions cause the processing device to perform operations further comprising:
in response to associating the block with the first plurality of blocks, performing, at a predefined frequency, another data integrity scan on the block to determine the one or more reliability statistics associated with the block.

20. The non-transitory computer-readable storage medium of claim 15, wherein, to identify the block of the memory device, the instructions cause the processing device to perform operations further comprising:
identifying that the block is associated with a folding operation, wherein data stored at the block is written to another block of the memory device.
